(19) United States
(12) Patent Application Publication
(10) Pub. No.: US 2006/0261359 A1
(43) Pub. Date: Nov. 23, 2006

(54) Heat sink for light emitting diode bulb

(76) Inventor: Hsien-Jung Huang, Yonghe City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/131,398

(22) Filed: May 18, 2005

(51) Int. Cl. H01L 33/00

(52) U.S. Cl. 257/98

(57) ABSTRACT

a heat sink for a light emitting diode lamp is disclosed. The heat sink comprises a heat sink module, a transparent lens and a heat condition liquid. The heat sink module has a lamphouse with a first opening and a second opening on the both ends. The heat sink is formed by a heat condition material for heat sinking. Besides, there is a room in where the heat condition liquid is filled within the heat sink module for enhancing the effect of heat condition. Accordingly, the heat can be sinked into the air by the heat sink module.

### BACKGROUND OF THE INVENTION

1. Field of the Invention

The present invention generally relates to a heat sink, and more particularly to a heat sink for a light bulb.

2. Description of the Prior Art

High brightness, low power consumption, long live time, and low working temperature are all of the advantages of the light emitting diodes (LED). The incandescent lamp has defects of the shot live time, high power consumption, and high working temperature by comparison. For examples, a flashlight with the light emitting diodes can be used over 50 hours by the power of three AAA batteries, and more particularly some flashlights with the light emitting diodes are guaranteed to be used over 70 hours. It is perceived that the power consumption of the light emitting diodes is very excellent.

For enhancing the brightness, a plurality of light emitting diodes are compounded to form a light emitting diode bulb. Although the working temperature of the light emitting diodes is low, a mount of light emitting diodes in a limited space could still generate a lot of heat. The heat could age or damage other components aside. Thus a better design for heat sinking is needed.

### SUMMARY OF THE INVENTION

Therefore, in accordance with the previous summary, objects, features and advantages of the present disclosure will become apparent to one skilled in the art from the subsequent description and the appended claims taken in conjunction with the accompanying drawings.

The present invention provides a heat sink for a light emitting diode lamp. The heat sink comprises a heat sink module, a transparent lens and a heat condition liquid. The heat sink module has a lamphouse with a first opening and a second opening on the both ends. The heat sink is formed by a heat condition material for heat sinking. Besides, there is a room in where the heat condition liquid is filled within the heat sink module for enhancing the effect of heat condition. Accordingly, the heat can be sinked into the air by the heat sink module.

### BREIF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1A is a profile diagram of one embodiment of the present invention; and

FIG. 1B, FIG. 1C, and FIG. 1D are the structure diagrams according to the embodiments of the present invention.

### DETAILIGHT EMITTING DIODE DESCRIPTION OF THE PREFERRED EMBODIMENTS

The present disclosure can be described by the embodiments given below. It is understood, however, that the embodiments below are not necessarily limitations to the present disclosure, but are used to a typical implementation of the invention.

Having summarized various aspects of the present invention, reference will now be made in detail to the description of the invention as illustrated in the drawings. While the invention will be described in connection with these drawings, there is no intent to limit it to the embodiment or embodiments disclosed therein. On the contrary the intent is to cover all alternatives, modifications and equivalents included within the spirit and scope of the invention as defined by the appended claims.

It is noted that the drawings presents herein have been provided to illustrate certain features and aspects of embodiments of the invention. It will be appreciated from the description provided herein that a variety of alternative embodiments and implementations may be realized, consistent with the scope and spirit of the present invention.

It is also noted that the drawings presents herein are not consistent with the same scale. Some scales of some components are not proportional to the scales of other components in order to provide comprehensive descriptions and emphasizes to this present invention.

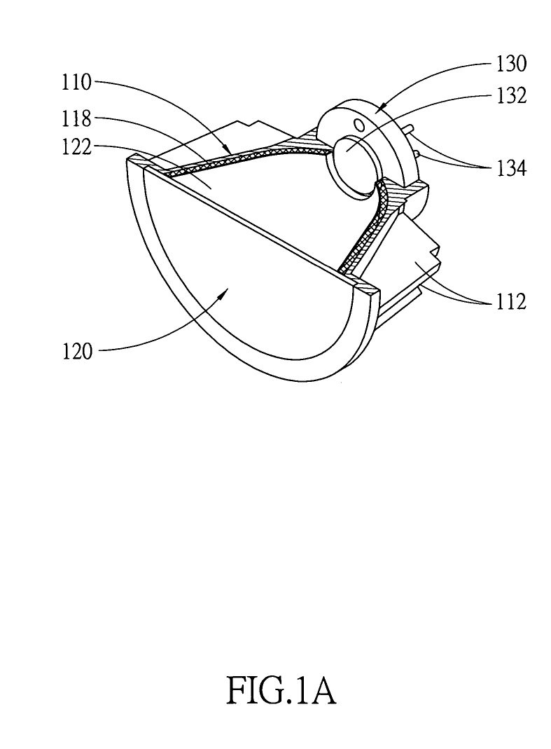

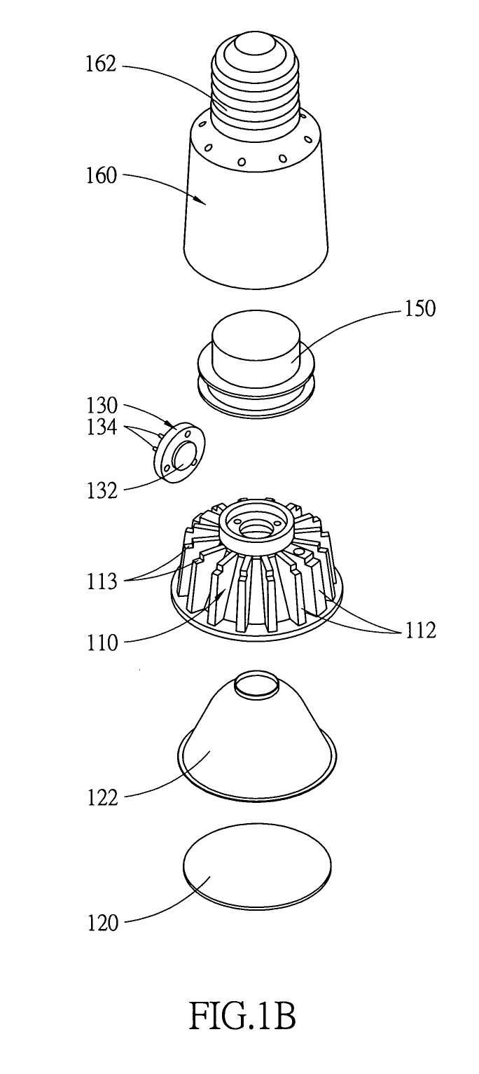

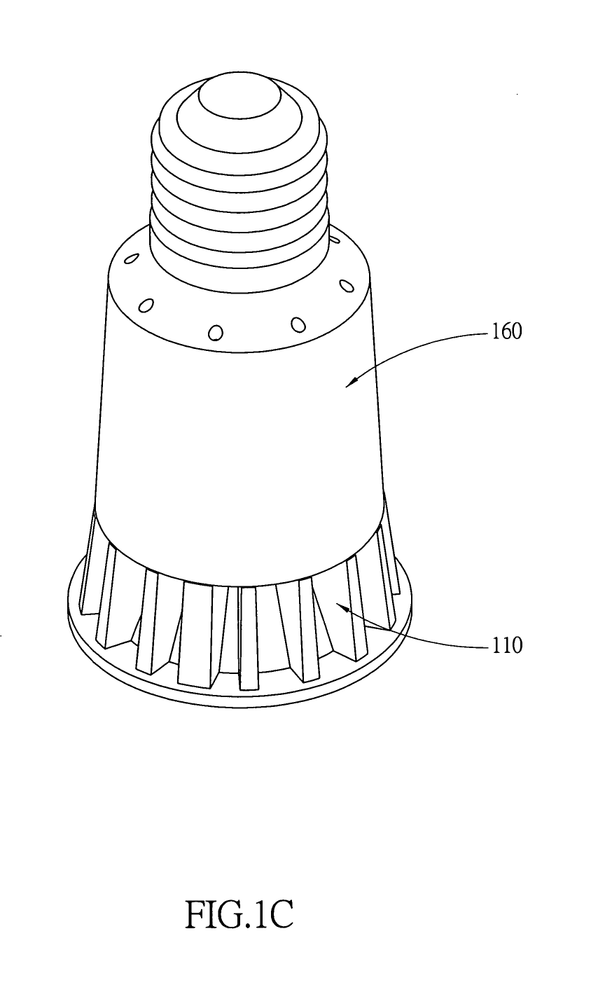

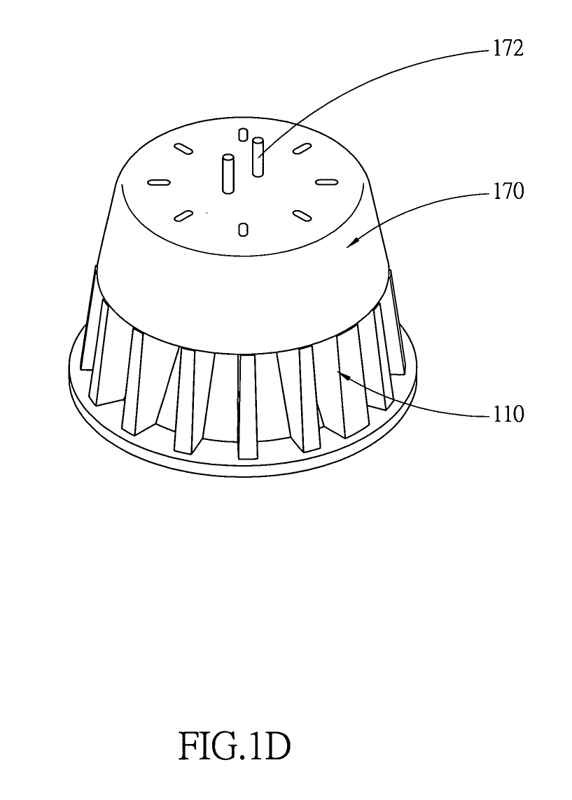

Referring to FIG. 1A, a structure diagram of a heat sink for a lamp of the light emitting diode is illustrated. The heat sink comprises a heat sink module 110, a transparent lens 120 and an illumination module 130. The heat sink 110 is formed by the heat condition materials for heat sinking. The heat sink 110 also has a plurality of cooling fins 112 surround it for increasing the cooling area. Besides, a lamphouse 122 is also included in the heat sink module 110 with a first opening and a second opening on the both ends. Moreover, the transparent lens 120 and the illumination module 130 are used for sealing the first opening and the second opening separately. Furthermore, the heat sink further comprises a sealed room 118 filled with a heat conduction liquid for enhancing the cooling effect of the heat sink 110. The room 118 can surround the lamphouse 122 for averagely conducting the heat to each cooling fins 1 12. According to one preferred embodiment of the present invention, the forgoing heat conduction liquid can be the ultra pure water, high thermal conductive liquid or high thermal conductive mixed liquid.

The forgoing illumination module 130 comprises at least a light emitting diode configured on the surface of the illumination module 130 toward the lamphouse. A light guiding material 132 can be cover on the light emitting diode or light emitting diodes. The light guiding material can be transparent or opaque. Besides, the illumination module 130 further comprises a plurality of terminals configured on the surface of the illumination module 130 backward the lamphouse 122. The terminals are used for electrically coupling a external electrical power for illumination. The forgoing external electrical power can be the alternating current or the direct current. The external electrical power is optional according to the type of the illumination module 130.

Referring to FIG. 1B and FIG. 1C, the tail of the heat sink module 110 can be connected to a connector 160, the connector 160 can include a screw cap 162, the interface for connecting the socket for a light bulb. The external electrical power is supplied via the socket for a light bulb. The standards of the screw cap can be E27, E39 and so forth. The present invention does not limit the manner for connecting the connector 160 with the heat sink module 110. For examples, there can be a indentation on a corner of each cooling fin 112, whereby connector 160 can be pressingly connected on the indentations of the heat sink 110.

Furthermore, one embodiment of the present invention can further an AC/DC converter (alternating current/direct current converter) module 150. The AC/DC converter can convert the alternating current in the external electrical power into the direct current for providing to the terminals 134.

Moreover, one embodiment of the present invention can further comprise a plurality of external terminals 172 on the connector 170, referring to FIG. 1D. Each external terminal 172 can be the extension of one of the terminals 134. The present invention does not limit the manner for connecting the connector 170 to the heat sink module 110.

Accordingly, the heat can be speeded up to conducting to the cooling fins of the heat sink module when the external electrical power is supplied to the light emitting diode, whereby the heat can be sinked into the air. The illumination module can also be other illumination devices except the light emitting diode, for examples, the incandescent lamps.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the inventions as determined by the appended claims when interpreted in accordance with the breath to which they are fairly and legally entitled.

It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

1. A heat sink for a light emitting diode bulb, comprising:
a heat sink module for heat sinking, wherein said heat sink module includes a lamphouse with a first opening and a second opening on the both sides of said lamphouse, wherein said heat sink module is formed by heat conduction materials and has a sealed room;
a transparent lens for sealing said first opening; and
a heat conduction liquid for conducting heat to said heat filled into said sealed room.

2. A heat sink for a light emitting diode bulb of claim 1, further comprising an illumination module for illuminating, wherein said second opening is sealed by said illumination module.

3. A heat sink for a light emitting diode bulb of claim 2, wherein said illumination module comprises at least a light emitting diode configured on the surface of said illumination module toward said lamphouse.

4. A heat sink for a light emitting diode bulb of claim 3, wherein there is a light guiding material cover said light emitting diode bulb.

5. A heat sink for a light emitting diode bulb of claim 4, wherein said light guiding material is opaque.

6. A heat sink for a light emitting diode bulb of claim 3, wherein said illumination module comprises a plurality of terminals configured on the surface of said illumination module backward said lamphouse, whereby said light emitting diode can use the external electrical power coupled with said terminals.

7. A heat sink for a light emitting diode bulb of claim 1, wherein said heat condition liquid is the ultra pure water.

8. A heat sink for a light emitting diode bulb of claim 1, wherein said heat condition liquid is a mixed liquid.

9. A heat sink for a light emitting diode bulb of claim 6, further comprising a connector with a screw cap, wherein said connector is connected with said heat sink module and said crew cap is used to connect a socket electrically coupling with an external electrical power.

10. A heat sink for a light emitting diode bulb of claim 6, further comprising a connector with a plurality of external terminals, wherein each external terminal is the extension of one of said terminals separately.

11. A heat sink for a light emitting diode bulb of claim 6, wherein said heat sink module further comprises a plurality of cooling fins surround said heat sink module, wherein cooling fins are formed by the heat condition materials for increasing the cooling area.
